(19) United States
(12) Patent Application Publication
(10) Pub. No.: US 2008/0061386 A1
(43) Pub. Date: Mar. 13, 2008

(54) SEMICONDUCTOR DEVICE INCLUDING A GATE ELECTRODE HAVING A POLYMETAL STRUCTURE

(75) Inventor: Tetsuya Taguwa, Tokyo (JP)

Correspondence Address: YOUNG & THOMPSON, 745 SOUTH 23RD STREET, 2ND FLOOR, ARLINGTON, VA, 22202, US

(73) Assignee: ELPIDA MEMORY, INC., Tokyo (JP)

(21) Appl. No.: 11/853,851

(22) Filed: Sep. 12, 2007

(30) Foreign Application Priority Data
Sep. 12, 2006 (JP) 2006-246222

(51) Int. Cl. H01L 29/78

(52) U.S. Cl. 257/412; 257/E29.255

(57) ABSTRACT

A semiconductor device includes a gate electrode including a polysilicon layer, a tungsten silicide layer, a tungsten nitride layer, and a tungsten layer, which are arranged in this order as viewed from a silicon substrate. The polysilicon layer is doped with phosphor, and the tungsten silicide layer is doped with nitrogen. The polysilicon layer is additionally doped with nitrogen in the top portion thereof.

This application is based upon and claims the benefit of priority from Japanese patent application No. 2006-246222, the disclosure of which is incorporated herein in its entirety by reference.

### BACKGROUND OF THE INVENTION

(a) Field of the Invention

The present invention relates to a semiconductor device including a gate electrode having a polymetal structure.

(b) Description of the Related Art DRAM (dynamic random access memory) devices include an array of memory cells each configuring a storage unit for storing therein a binary data. The memory cell includes a MOSFET (metal-oxide-semiconductor field-effect-transistor) formed in a surface region of a semiconductor substrate and a capacitor connected to the MOSFET, and stores therein data by storing electric charge in the capacitor via the MOSFET.

A polymetal structure is widely adopted as the structure of the gate electrode of the MOSFET configuring a word line of the DRAM devices. The polymetal structure is such that a metallic layer including a refractory metal, such as tungsten (W), overlies a polysilicon layer doped with impurities. The polymetal structure has the advantage of lower line resistance or sheet resistance compared to the conventional polycide structure, wherein a silicide layer is formed on a polysilicon layer. The polymetal structure is increasingly used for the gate electrode in the DRAM devices for the purpose of achieving a higher-speed operation and a finer design rule thereof.

It is generally known in the art that the metallic layer in the polymetal structure, if formed directly on the polysilicon layer, causes a reaction between the polysilicon layer and the metallic layer to thereby form a thick metal silicide layer. The metallic silicide layer generally has a higher resistivity to raise the line resistance of the gate electrode. Thus, it is essential in the polymetal structure of the DRAM devices to suppress the reaction between the metal silicide layer and the polysilicon layer in order for achieving a higher-speed operation.

Patent Publication JP-1999-233451A describes a technique for forming a metal silicide nitride layer by using the steps of depositing a metal nitride layer on the polysilicon layer, and heat treating the deposited metal nitride layer to react with the polysilicon layer before depositing a metallic layer thereon.

In the technique described in the above publication, the direct contact between the metal nitride layer and the polysilicon layer produces a metal silicide nitride layer having a large thickness during the heat treatment, and may cause a higher interface resistance in the vicinity of the metal silicide nitride layer depending on the composition and structure of the layered gate electrode. Patent Publication 2003-163348A describes another technique of forming a metal nitride layer on the polysilicon layer with an intervention of a metal silicide layer therebetween. In this technique, the metal silicide layer intervening between the polysilicon layer and the metal nitride layer prevents formation of the thick metal silicide nitride layer, thereby suppressing the increase in the interface resistance.

The present inventor analyzed the technique of JP-2003-163348A, and noted the following facts. In general, an exposed surface of the metal silicide layer is liable to spontaneous oxidation to form a native oxide film. The thus formed native oxide film has a higher electric resistivity and thereby increases the interface resistance in the vicinity of the metal silicide layer such as between the metal silicide layer and the metal silicide nitride layer. Accordingly, formation of the native oxide film should be suppressed in order for achieving the higher-speed DRAM devices. In view of this fact, JP-2003-163348A employs a wet treatment using a hydrofluoric acid before deposition of the metal nitride layer to thereby remove the native oxide film.

In a typical process for forming the gate electrode, a significant amount of works, such as transferring the wafer and treatment of the filming device, is generally necessary between the wet treatment and the deposition of the metal nitride layer. This may cause formation of another native oxide film in the time interval between the wet treatment and formation of the metal nitride layer, to increase the interface resistance. In order to suppress formation of the another native oxide film the time interval between the wet treatment and deposition of the metal nitride layer should be reduced, which increases the restrictions on the fabrication process, however.

### SUMMARY OF THE INVENTION

In view of the above, it is an object of the present invention to provide a semiconductor device which is capable of suppressing the increase in the interface resistance caused by the spontaneous oxidation of silicide of a refractory meal while reducing the restrictions on the fabrication process thereof.

The present invention provides a semiconductor device including: a semiconductor substrate; and a gate electrode including a polysilicon layer, a silicide layer including silicide of a refractory metal, a nitride layer including nitride of the refractory metal, and a metallic layer including the refractory metal, which are formed in this order as viewed from the semiconductor substrate, wherein the polysilicon layer is doped with first impurities which allow the polysilicon layer to have an electric conductivity, and the silicide layer is doped with second impurities which suppress oxidation of the silicide layer.

The above and other objects, features and advantages of the present invention will be more apparent from the following description, referring to the accompanying drawings.

### BRIEF DESCRIPTION OF THE DRAWINGS

FIG. 1 is a sectional view of a semiconductor device according to an exemplary embodiment of the present invention.

FIGS. 2A to 2F are sectional views of the semiconductor device of FIG. 1 in consecutive steps of a fabrication process thereof.

### PREFERRED EMBODIMENT OF THE INVENTION

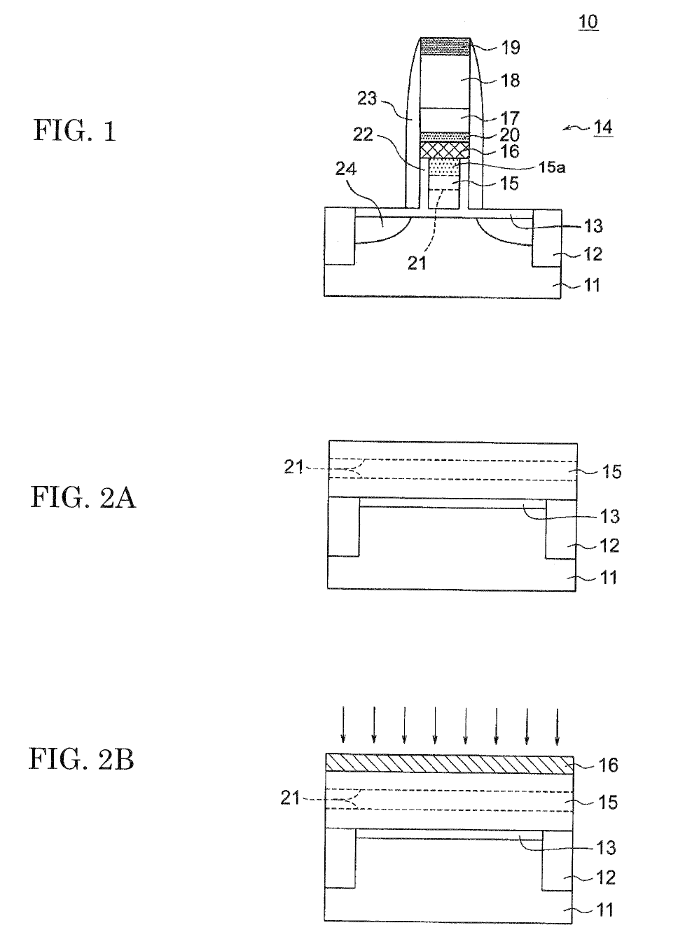

Now, an exemplary embodiment of the present invention will be described with reference to the accompanying drawings. FIG. 1 shows a sectional view of a semiconductor device according to the exemplary embodiment of the present invention. The semiconductor device, generally designated at numeral 10, is configured as a DRAM device, and includes a p-type silicon substrate 11. In the surface region of the silicon substrate 11, there is provided a shallow-trench-isolation (STI) structure to isolate the surface region of the silicon substrate 11 into an array of device areas, in each of which a MOSFET is formed. A gate insulating film 13 is formed on the surface of the silicon substrate 11 in the device areas.

On the gate insulating film 13, there are formed a gate electrode 14 and an overlying protective film 19 which are patterned to have a specific shape. The gate electrode 14 includes polysilicon (poly-Si) layer 15, tungsten silicide (WSi₂) layer 16, tungsten silicide nitride (WSiN) layer 20, tungsten nitride (WN) layer 17 and tungsten (W) layer 18, which are consecutively arranged from the bottom. The overlying protective film 19 is made of silicon nitride. The WSiN layer 20 is a thin amorphous layer, which is formed by a reaction between the WSi₂ layer 16 and the tungsten nitride layer 17 during a high-temperature heat treatment. A sidewall oxide film 22 is provided on the side surface of the polysilicon layer 15.

The polysilicon layer 15 is doped with n-type impurities (first impurities) such as phosphor (P). The polysilicon layer 15 includes three layer sections having different crystal orientations, and the interface between adjacent two of the layer sections is configured by a crystal grain interface 21. The crystal grain interface 21 has a function of suppressing diffusion of a metal, whereby the tungsten is prevented from diffusing toward the silicon substrate 11, to thereby improve the reliability of the gate insulating film 13.

The polysilicon layer 15 is additionally doped with nitrogen (second impurities) in the top portion 15a thereof. The nitrogen atoms in the WSi₂ layer 16 and the doped portion 15a of the polysilicon layer 15 prevent the WSi₂ layer 16 and polysilicon layer 15 from receiving therein oxygen atoms. The polysilicon layer 15 is about 100 nm thick, and the nitrogen is introduced substantially uniformly in the doped portion 15a which is located between the top of the polysilicon layer 15 and a depth of about 5 to 20 nm measured therefrom. The purpose of introducing the nitrogen only in the top portion 15a of the polysilicon layer 15 is to suppress an increase in the overall electric resistance of the polysilicon layer 15.

The WSi₂ layer 16 is doped with phosphor and nitrogen. The purpose of doping the WSi₂ layer 16 with phosphor is to prevent the phosphor introduced in the polysilicon layer 15 from diffusing toward the WSi₂ layer 16, whereas the purpose of doping the WSi₂ layer 16 with nitrogen is to prevent the spontaneous oxidation of the surface of the WSi₂ layer 16. The thickness of the WSi₂ layer 16 is preferably between 3 nm and 15 nm, and may be 7 nm, for example.

A sidewall protective film 23 is formed on the side surface of the gate electrode structure including the gate electrode 14, overlying protective film 19 and sidewall oxide film 22. A portion of the silicon substrate 11 adjacent to the gate electrode 14 is heavily doped with impurities to configure source/drain regions 24 of the MOSFET. Arsenic (As) is doped in the source/drain region 24 of the NMOSFET, whereas boron (B) is doped in the source/drain region 24 of the PMOSFET.

The WSi₂ layer 16 doped with nitrogen has a surface which is less liable to the spontaneous oxidation. The polysilicon layer 15 having the top portion 15a doped with nitrogen suppresses oxygen from diffusing from the WSi₂ layer 16 to the polysilicon layer 15, even if the WSi₂ layer is oxidized, whereby the surface of the polysilicon layer 15 is less liable to the spontaneous oxidation. Thus, the interface between the WSi₂ layer 16 and the WSiN layer 20, and the interface between the polysilicon layer 15 and the WSi₂ layer 16 have a lower electric resistivity, to thereby raise the operational speed of the semiconductor device 10.

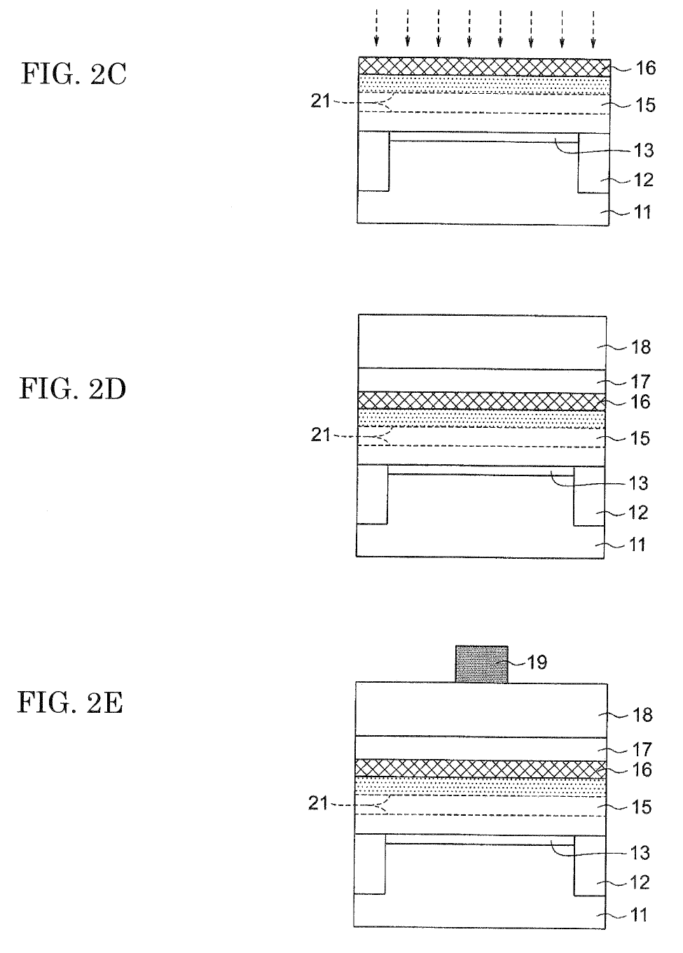

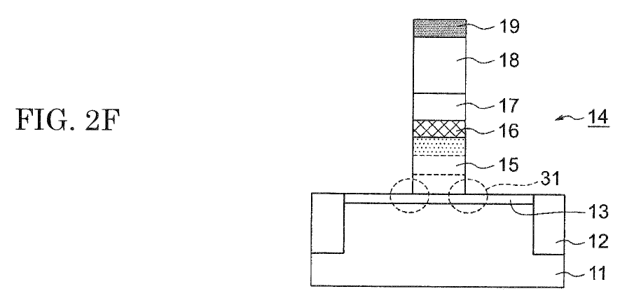

FIGS. 2A to 2F show the semiconductor device 10 in consecutive steps of a fabrication process thereof. The STI structure 12 including therein a silicon oxide film is first formed in the surface region of the p-type silicon substrate 11, thereby forming device areas in the silicon substrate 11. The gate insulating film 13 is then formed on the surface of the silicon substrate 11 in the device areas. The process for forming the gate insulating film 13 is such that the silicon substrate 11 is maintained at a substrate temperature of 850 degrees C., in a steam- and oxygen-containing atmosphere for about four hours, to thereby form a 4 nm-thick oxide film.

Thereafter, a polysilicon layer 15 doped with phosphor is deposited on the gate insulating film 13, as shown in FIG. 2A. For example, the deposition of the polysilicon layer 15 is such that the silicon substrate 11 is maintained at a substrate temperature of 580 degrees C., under a deposition chamber pressure of 100 Pa, in an atmosphere of monosilane (SiH₄) supplied at a flow rate of 3 slm (standard litters per minute) and phosphine (PH₃) supplied at a flow rate of 70 sccm (standard cubic centimeters per minute) for about one hour, to form a 100-nm-thick polysilicon layer. The polysilicon layer 15 thus formed has a phosphorous concentration of about 2×10²⁰ atoms/cm³, for example.

The process for deposition of the polysilicon layer 15 is separated into several steps to form different layer sections having different crystal orientations. In the exemplary embodiment, the process is separated into three steps to form two crystal grain interfaces 21 between the layer sections within the polysilicon layer 15.

Subsequently, the polysilicon layer 15 is subjected to a wet surface treatment using a mixture of hydrofluoric acid and hydrogen peroxide for about one minute, thereby cleaning the surface of the polysilicon layer 15 and removing the native oxide film formed thereon. Thereafter, a 7-nm-thick WSi₂ film 16 is deposited using a CVD (chemical vapor deposition) process. The CVD process may be replaced by a sputtering process; however, the CVD process is more preferable because the CVD process provides a superior controllability of the film thickness. The CVD process for forming the WSi₂ layer is such that the silicon substrate is maintained at a substrate temperature of 550 degrees C., under an atmosphere including dichlorosilane (Si₂H₂) supplied at a flow rate of 200 sccm and tungsten hexafluoride (WF₆) supplied at a flow rate of 2 sccm for about 30 seconds, thereby forming a 7-nm-thick WSi₂ layer 16.

The thickness of the WSi₂ layer 16 is not limited to 7 nm, and may be preferably in the thickness range of 3 to 15 nm. A larger film thickness larger than 15 nm may cause a difficulty in the later patterning processing of the gate electrode 14, and a peel-off of the tungsten nitride layer 17 from the WSi₂ layer 16. The peel-off may occur particularly in a heat treatment conducted after deposition of the layers 15 to 19 of the gate electrode and reduces the reliability of the semiconductor device 10. On the other hand, a smaller thickness smaller than 3 nm may cause a mechanical stress on the gate insulating film 13, the mechanical stress being caused by agglomeration of WSi₂ occurring during a high-temperature heat treatment. The stress may degrade the reliability of the gate insulating film 13, and will be more noticeable along with a smaller thickness of the gate insulating film 13.

Thereafter, as shown in FIG. 2B, an ion-implantation process is conducted to introduce phosphor into the WSi₂ layer 16 for the purpose of preventing reduction of the impurity density in the top portion of the polysilicon layer 15. It is noted here that the diffusion coefficient of the impurities is larger in the WSi₂ layer 16 than in the silicon by about three to six orders of magnitude. Thus, without this ion implantation, the impurities in the top portion of the polysilicon layer 15 may be diffused in a large amount toward the WSi₂ layer 16 depending on the thickness of the tungsten layer 18 and the conditions of the heat treatment, to raise the electric resistance of the interface between the polysilicon layer 15 and the WSi₂ layer 16.

Introduction of phosphor into the WSi₂ layer 16 employs an acceleration energy of 10 keV and a dosage of 5×10¹⁵ atoms/cm². The phosphor may be replaced by arsenic (As), for example. Alternatively, a higher impurity concentration of the polysilicon layer 15 may be employed instead of introduction of phosphor into the WSi₂ layer 16. The introduction of phosphor into the WSi₂ layer 16 also improves the heat resistance of the WSi₂ layer 16, and suppresses the peel-off of the layers 1 to 19 during the heat treatment. This effect is noticeable along with an increase of the thickness of the WSi₂ layer 16.

Subsequently, as shown in FIG. 2C, nitrogen is introduced into the WSi₂ layer 16 and the top portion of the polysilicon layer 15 by an ion-implantation technique. The acceleration energy of nitrogen implantation may be in the range of 3 to 30 keV, and may be 5 keV, for example. This acceleration energy allows the implanted nitrogen to penetrate the WSi₂ layer 16 to reach a depth of 5 to 20 nm as measured from the top of the polysilicon layer 15. The dosage is preferably in the range of 5×10¹⁴ to 5×10¹⁵ atoms/cm², and may be 8.0×10¹⁴ atoms/cm^{,} for example. The nitrogen implantation through the WSi₂ layer 16 introduces the nitrogen into the top portion of the polysilicon layer 15 with a superior controllability and a uniform density.

Thereafter, a RTA (rapid thermal annealing) treatment is performed for the purpose of removing the residual gas from the WSi₂ layer 16, the residual gas being received in the WSi₂ layer 16 during the CVD process thereof. In the conventional process for forming the semiconductor device, the residual gas remaining in the WSi₂ layer 16 has a tendency of concentrating in the interface between the WSi₂ layer 16 and the tungsten nitride layer 17, causing degradation in the adhesiveness therebetween, a peel-off and increase in the interface resistance. The present embodiment prevents such problems.

During the RTA treatment, the silicon substrate is maintained in an atmosphere including argon, nitrogen or ammonia for 60 seconds at a substrate surface temperature of 850 degrees C. The substrate surface temperature may be 700 degrees C. or above. An excessively higher substrate surface temperature or an excessively longer time treatment may allow impurities to be discharged from the silicon substrate 11, to raise the interface resistance between the polysilicon layer 15 and the WSi₂ layer 16 or to raise the threshold voltage of the MOSFET. Thus, it is preferable to maintain the substrate surface temperature at 1000 degrees C. or below, and to employ a suitable treatment time length.

The RTA treatment, which raises the substrate surface temperature within a short period of time, suppresses diffusion of the nitrogen within the polysilicon layer 15 while removing a sufficient amount of residual gas. This reduces the overall electric resistance of the polysilicon layer 15 and suppresses depletion thereof. The RTA treatment has also other functions of stabilizing the layers deposited prior to the RTA treatment, such as activating the impurities in the polysilicon layer 15, recovering the crystalline property of the polysilicon layer 15, and crystallizing the WSi₂ layer 16.

Subsequently, a wet treatment using hydrofluoric acid is conducted to the substrate surface for about 30 seconds, thereby cleaning the surface of the WSi₂ layer 16 and removing the native oxide film formed thereon. The wet treatment is preferably conducted for a time period corresponding to the etching time length of an equivalent oxide thickness of 1 nm. An excessively smaller time length for the etching degrades the adhesive property of the tungsten nitride layer 17 with respect to the WSi₂ layer 16, whereas an excessively larger time length for the etching degrades the morphology of the WSi₂ layer 16, to affect the property of the tungsten nitride layer 17 deposited on the WSi₂ layer 16 and increase the electric resistivity of the tungsten nitride layer 17.

Subsequently, a 10-nm-thick tungsten nitride layer 17 and a 80-nm-thick tungsten layer 18 are consecutively deposited on the WSi₂ layer 16, as shown in FIG. 2D. The tungsten nitride layer 17 is provided as a barrier layer for preventing a reaction between the tungsten layer 18 and the WSi₂ layer 16 or polysilicon layer 15, whereas the tungsten layer 18 is provided for the purpose of reducing the line resistance of the gate electrode due to the lower resistivity thereof. The deposition of the tungsten nitride layer 17 and tungsten layer 18 may use a CVD technique or a sputtering technique, the latter being used in this example.

The deposition of the tungsten nitride layer 17 by using the sputtering technique is performed in a vacuum chamber wherein a tungsten target is provided. In the sputtering, the target is heated up to a temperature of about 200 degrees C., the internal pressure of the chamber is set at 10 mTorr, argon and nitrogen are supplied at flow rates of 40 sccm and 60 sccm, respectively, and a 800-watt DC power is applied to the process to generate plasma in the chamber. The plasma thus generated sputters tungsten out of the target and allows the sputtered tungsten to react with active nitrogen generated in the plasma, whereby tungsten nitride is generated and then deposited onto the substrate. The process is conducted for twenty minutes to provide a 10 nm-thick tungsten nitride layer 17.

It is preferable that the tungsten nitride layer 17 have a thickness of 5-20 nm. A smaller thickness of the tungsten nitride layer 17 smaller than 5 nm may cause an insufficient barrier property, whereas a larger thickness of the tungsten nitride layer 17 larger than 20 nm may cause a difficulty in the patterning of the gate electrode 14. The insufficient barrier function, if occurs, causes reaction between the overlying tungsten layer 18 and silicon in the underlying WSi₂ layer or in the underlying polysilicon layer 15, to generate a WSi layer from at least a part of the tungsten layer 18. This raises the line resistance of the gate electrode 14 as well as an abnormal growth of the tungsten layer 18 to degrade the reliability of the semiconductor device 10.

Deposition of the tungsten nitride layer 17 may be preferably conducted under the condition that the ratio of tungsten to nitrogen (W/N) is set at 0.8 to 2.0. This is because the composition of the tungsten nitride layer 17 largely affects the heat resistant property thereof, and a ratio of about 1.7, for example, prevents desorption of nitrogen during the heat treatment using the RTA technique even at a temperature of 1000 degrees C. for 60 seconds.

Deposition of the tungsten layer 18 follows the deposition of the tungsten nitride layer 17 by stopping supply of the nitrogen gas, to thereby generate plasma including only argon gas, and raising the DC power up to 1500 watts. The silicon substrate is maintained in this state for 40 seconds to deposit thereon an 80 nm-thick tungsten layer 18. Deposition of the tungsten nitride layer 17 and tungsten layer 18 in this manner maintains the normal barrier function of the tungsten nitride layer 17 during the high-temperature heat treatment after deposition of the layers 15 to 19, thereby providing a gate electrode 14 having a lower line resistance.

A 200 nm-thick silicon nitride layer is then deposited using a CVD technique onto the tungsten layer 18, followed by forming a resist film thereon by coating. Subsequently, the resist film is patterned using a photolithographic technique to form a resist pattern having a gate electrode pattern. A dry etching is then conducted to pattern the silicon nitride film to form the overlying protective film 19 having the gate electrode pattern, followed by removing the resist pattern as shown in FIG. 2E.

The substrate surface is then cleaned, and thereafter, a dry etching process using the overlying protective film 19 is conducted to pattern the tungsten layer 18, tungsten nitride layer 17, WSi₂ layer 16 and polysilicon layer 15 to form the gate electrode 14 including these conductive films 15 to 18, as shown in FIG. 2E This dry etching process may damage a portion of the gate insulating film 13 in the vicinity of the bottom side portion 31 of the gate electrode 14.

Subsequently the substrate surface is thermally treated for the purpose of improving the profile of the gate insulating film 13. In this heat treatment, the silicon substrate is received in a chamber, heated up to 800 degrees C. and maintained in this state for about one hour, whereby the exposed silicon surface is oxidized, damage of the gate insulating film 13 is remedied, and a 5-nm-thick sidewall oxide film 22 is formed on the side surface of the polysilicon layer 15.

A silicon nitride film is then deposited on the entire surface to a thickness of 40 nm, followed by etch-back thereof to leave the sidewall protective film 23 on the side surface of the gate electrode 14, overlying protective film 19 and sidewall oxide film 22.

After forming a resist pattern which covers the device regions for the PMOSFET, the device regions for the NMOSFET are heavily doped with arsenic by ion-implantation using the gate electrode structure as a mask, to thereby form source/drain regions 24. Subsequently, after forming another resist pattern which covers the device regions for the NMOSFET, the device regions for the PMOSFET are heavily doped with boron difluoride by ion-implantation using the gate electrode structure as a mask, to thereby form source drain regions 24.

Subsequently, a heat treatment is performed at 950 degrees C. for 10 seconds as by RTA for the purpose of activating the doped impurities. This heat treatment forms a thin amorphous WSiN layer 20 between the WSi₂ layer 16 and the tungsten nitride layer 17 shown in FIG. 1. The WSiN layer 20 formed between the WSi₂ layer 16 and the tungsten nitride layer 17 has a barrier function against the tungsten layer 18, and also suppresses diffusion of phosphor introduced in the WSi₂ layer 16. Alternatively, the heat treatment may be performed directly after deposition of the tungsten nitride layer 17 and tungsten layer 18 to form the WSiN layer 20.

In the process as described above, since nitrogen is introduced in the WSi₂ layer 16 and the top portion of the polysilicon layer 15, the spontaneous oxidation of the WSi₂ layer 16 and polysilicon layer 15 can be suppressed. This suppresses the increase of the interface resistance in the vicinity of the WSi₂ layer 16 while alleviating the restrictions on the fabrication process.

Since the nitrogen is introduced in the top portion of the polysilicon layer 15 through the WSi₂ layer 16, the introduction of nitrogen is well controlled to restrict the introduced region to a small depth within the polysilicon layer 15. This prevents an undesirable increase of the overall resistance of the polysilicon layer 15.

The above RTA treatment for removing the residual gas within the WSi₂ layer 16 is often employed for a variety of purposes including activation of impurities after implantation thereof and sinter of the interlevel dielectric film. In such a case, the RTA treatment may use different ambient gases, such as oxygen, depending on the desired purposes. In the conventional technique, even a small amount of oxygen, if it remains in the chamber after the heat treatment, may oxidize the top surface of the polysilicon layer 15 to raise the resistivity thereof.

Further, oxygen gas may remain after a typical maintenance treatment of the RTA chamber by using the oxygen gas. In the conventional technique, the remaining oxygen gas may oxidize the surface of the polysilicon layer even in a process without using an oxygen atmosphere. On the other hand, in the process of the above embodiment, since the nitrogen introduced in the top portion of the polysilicon layer 15 suppresses oxidation of the polysilicon layer 15 caused by the oxygen in the conventional technique.

Although the nitrogen is introduced in the WSi₂ layer and the top portion of the polysilicon layer in the above embodiment, nitrogen may be replaced by other impurities so long as the other impurities suppress oxidation of those layers of the gate electrode. The refractory metal may be chrome, tantalum, titanium etc. other than the tungsten.

While the invention has been particularly shown and described with reference to exemplary embodiment and modifications thereof, the invention is not limited to these embodiment and modifications. It will be understood by those of ordinary skill in the art that various changes in form and details may be made therein without departing from the spirit and scope of the present invention as defined in the claims.

What is claimed is:

1. A semiconductor device comprising:
a semiconductor substrate; and
a gate electrode including a polysilicon layer, a silicide layer including silicide of a refractory metal, a nitride layer including nitride of said refractory metal, and a metallic layer including said refractory metal, which are formed in this order as viewed from said semiconductor substrate,
wherein said polysilicon layer is doped with first impurities which allow said polysilicon layer to have an electric conductivity, and said silicide layer is doped with second impurities which suppress oxidation of said silicide layer.

2. The semiconductor device according to claim 1, wherein said polysilicon layer is additionally doped with said second impurities in a top portion thereof.

3. The semiconductor device according to claim 1, wherein said silicide layer is additionally doped with said first impurities.

4. The semiconductor device according to claim 1, wherein said gate electrode further comprises a silicide nitride layer including silicide nitride of said refractory metal between said silicide layer and said nitride layer, said silicide nitride layer having a thickness smaller than a thickness of said silicide layer.

5. The semiconductor device according to claim 1, wherein said first impurities include phosphor and/or arsenic.

6. The semiconductor device according to claim 1, wherein said second impurities include nitrogen.

7. The semiconductor device according to claim 1, wherein said polysilicon layer includes three layer sections having different crystal orientations.
